(19) United States
(12) Patent Application Publication
(10) Pub. No.: US 2018/0323078 A1
(43) Pub. Date: Nov. 8, 2018

(54) PITCH DIVISION USING DIRECTED SELF-ASSEMBLY

(71) Applicant: Intel Corporation, Santa Clara, CA (US)

(72) Inventors: Stephanie A. BOJARSKI, Sherwood, OR (US); Manish CHANDHOK, Beaverton, OR (US); Todd R. YOUNKIN, Portland, OR (US); Eungnak HAN, Portland, OR (US); Kranthi Kumar ELINENI, Hillsboro, OR (US); Ashish N. GAIKWAD, Hillsboro, OR (US); Paul A. NYHUS, Portland, OR (US); Charles H. WALLACE, Portland, OR (US); Hui Jae YOO, Hillsboro, OR (US)

(21) Appl. No.: 15/774,255

(22) PCT Filed: Dec. 24, 2015
(86) PCT No.: PCT/US2015/000380

§ 371 Date: May 7, 2018

(51) Int. Cl. H01L 21/311; H01L 21/033

(52) U.S. Cl. CPC H01L 21/31144; H01L 21/0338; H01L 21/0337

(57) ABSTRACT

A method including forming a target pattern of a target material on a surface of a substrate; depositing a block copolymer on the surface of the substrate, wherein one of two blocks of the block copolymer preferentially aligns to the target material and the two blocks self assemble after deposition into repeating lamellar bodies on the surface of the substrate; selectively retaining one of the two blocks of the block copolymer over the other as a polymer pattern; and patterning the substrate with the polymer pattern. An apparatus including an integrated circuit substrate including a plurality of contact points and a dielectric layer on the contact points; a target pattern formed in a surface of the dielectric layer; and a self-assembled layer of repeating alternating bodies of a block copolymer, wherein one of two blocks of the block copolymer is preferentially aligned to the target pattern.

### BACKGROUND

### Field

Integrated circuit processes.

### Description of Related Art

Lithography is not generally scaling in pace with Moore's law. The current process technologies typically use a spacer based method of pitch division to create small pitch features. With the current state of art, resulting features exhibit generally poor critical dimension uniformity (CDU), are increasingly expensive to manufacture, and exhibit generally poor line edge roughness (LER).

### BRIEF DESCRIPTION OF THE DRAWINGS

FIG. 1 shows a cross-sectional side view of a portion of an integrated circuit structure, including a substrate, circuit devices and one or more optional interconnect levels, an interlayer dielectric layer, and first, second and third layers of mask layers, a sacrificial substrate layer, an antirefelction layer and a photoresist layer patterned with a first pitch thereon;

FIG. 2 shows the structure of FIG. 1 following the patterning of a third hard mask layer through the mask defined by photoresist layer;

FIG. 3 shows the structure of FIG. 2 following the conformal deposition of a spacer layer on a surface of the structure;

FIG. 4 shows the structure FIG. 3 following the anisotropic etching of the spacer layer, a removal of the third hard mask layer and the forming openings through the sacrificial substrate layer;

FIG. 5 shows the structure of FIG. 4 following the deposition of a target material over the surface and in the openings through the sacrificial substrate layer;

FIG. 6 shows the structure of FIG. 5 following the planarization of the substrate surface to remove the target material from a surface of the structure;

FIG. 7 shows the structure of FIG. 6 following the introduction of a directed self-assembly alignment promotion (DSAAP) layer on a surface of target material 195 where such DSAAP is tailored for one of a block (a polymer) of a block copolymer of a DSA material to be subsequently introduced and the introduction of a neutral DSAAP;

FIG. 8 shows the structure of FIG. 7 following the introduction of a block copolymer on the structure according to a DSA process that forms repeating alternating lamellar bodies of the blocks of the block copolymer;

FIG. 9 shows the structure of FIG. 8 following the selective removal of one of the lamellar bodies and the hardening of the retained lamellar bodies to form a polymer pattern;

FIG. 10 shows the structure of FIG. 9 following the introduction of a hard mask complementary to the polymer pattern;

FIG. 11 shows the structure of FIG. 10 following the selective removal of the lamellar bodies to leave a patterned hard mask on the surface of the structure;

FIG. 12 shows the structure of FIG. 11 following the etching of the sacrificial substrate layer with the hard mask as a pattern;

FIG. 13 shows the structure of FIG. 12 following the etching of the second hard mask layer using the patterned second substrate layer as a mask;

FIG. 14 shows the structure of FIG. 13 following the forming of trenches in the ILD layer with the second hard mask 130 used as a mask;

FIG. 15 shows the structure of FIG. 14 following the introduction of interconnects in the trenches;

FIG. 16 shows a cross-sectional side view of an integrated circuit structure according to another embodiment where a target material on the structure is used to pin two of particular block of a block copolymer.

FIG. 17 is an interposer implementing one or more embodiments; and

FIG. 18 illustrates an embodiment of a computing device.

### DETAILED DESCRIPTION

A method of creating small pitch features using directed self-assembly (DSA) and creating tight-pitch interconnects is disclosed. DSA is a process where a guide on a surface is used to align a lamellar block copolymer. In one embodiment, a target material is introduced that facilitates self-alignment of DSA materials to form a pattern. A target material, in one embodiment, is a material on a substrate such as a metal or other material that can be modified to attract a block (a polymer) of a DSA block copolymer relative to another material on the substrate and direct the self-alignment of the block copolymer. In one embodiment, the target material is patterned as loose pitch (large pitch) lines on a substrate and used as a template for a tighter pitch DSA patterning scheme. A method includes forming a target pattern of a target material on a surface of a substrate; depositing a block copolymer on the surface of the substrate, wherein one of two block (polymers) of the block copolymer preferentially aligns to the target material or a directed self-assembly promotion (DSAAP) layer on the target material and the two blocks of the copolymer self assemble after deposition into repeating lamellar bodies (alternating one after the other in a repeating pattern); selectively retaining one of the two blocks of the block copolymer over the other as a polymer pattern; and patterning the substrate with the polymer pattern. Patterning the substrate can include patterning one or more underlying sacrificial substrate layers to transfer the pattern to such one or more sacrificial substrate layers and etching openings in the substrate. In one embodiment, the openings in the substrate may be filled with interconnect material.

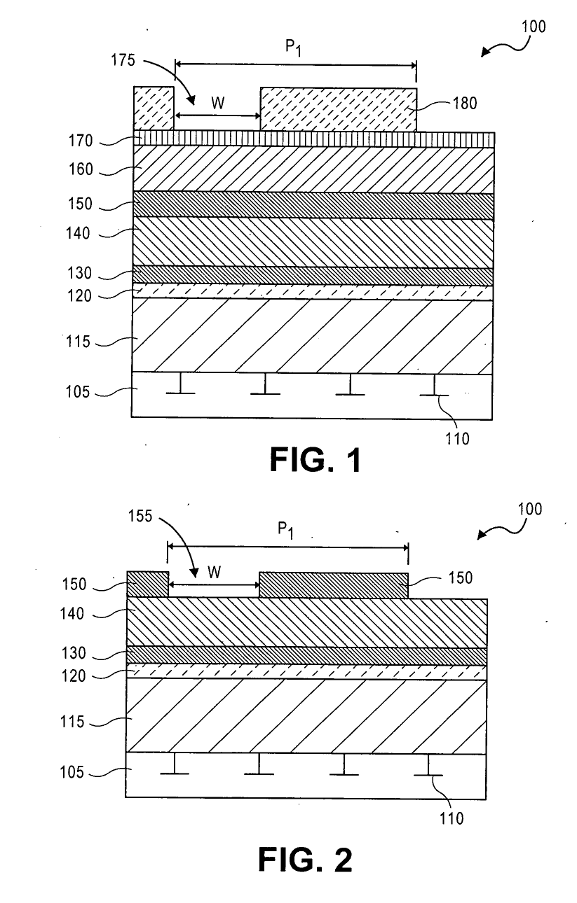

FIGS. 1-15 describe one embodiment of forming an interconnect level or layer of a plurality of interconnects in an integrated circuit structure. More specifically, FIGS. 1-15 describe a process of pitch quartering using DSA with a single lithography pass and mask transfer layers. Referring to FIG. 1, FIG. 1 shows an embodiment of a portion of an integrated circuit structure. Such structure may be a portion of a wafer that is designated for hundreds of discrete integrated circuit chips. FIG. 1 shows structure 100 including substrate 105 of, for example, a semiconductor material such as silicon, germanium, or other material. Substrate 105, in one embodiment, includes circuit devices, such as transistors and other devices (e.g., memory devices, capacitors) formed on a semiconductor surface and optionally one or more levels of interconnect to such circuit devices. Devices 110 in FIG. 1 may be a circuit device (e.g., a transistor or other device) formed as part of a device level in or on a semiconductor substrate or on interconnect layer or level formed above a device level and connected to a lower level interconnect level and/or to a circuit device(s) at the device level through, for example, a conductive via. It is appreciated that techniques described herein may be used for various interconnects within an integrated circuit including interconnects to devices that include circuit devices and other interconnects. In this sense, devices 110 represents where an interconnect contact may be made.

Disposed on overlying a surface (top surface as viewed) of devices 110 and substrate 105 is interlayer dielectric (ILD) layer 115 as a feature layer. In one embodiment, ILD layer 115 is a silicon dioxide (SiO₂) or a dielectric material having a dielectric constant less than a dielectric constant of silicon dioxide (e.g., a “low k” material). Representative low k material includes materials containing silicon carbon and oxygen (e.g., polymers) that are known in the art. Overlying ILD layer 115, in this embodiment, is first hard mask layer 120. First hard mask layer 120 is, for example, a silicon nitride (SiₓN_{y}) or other material that can serve, in one aspect, to protect underlying ILD layer 115 from undesired etching with respect to etch processes that may be performed on overlying layers. In one embodiment, first hard mask layer 120 has a thickness on the order of 5 nanometers (nm)-50 nm.

Overlying first hard mask layer 120 in the embodiment of structure 100 in FIG. 1 is second hard mask layer 130. In one embodiment, second hard mask layer 130 is a material that has an etch rate for a particular etchant that is different than a material for first hard mask layer 120. Where first hard mask layer 120 is silicon nitride, a suitable material for second hard mask layer 130 is titanium nitride (TiN). A representative thickness of second hard mask layer 130 of titanium nitride is on the order of 5-50 nm.

Overlying second hard mask layer 130 in the embodiment of structure 100 shown in FIG. 1 is sacrificial substrate layer 140. In one embodiment, sacrificial substrate layer 140 may be used to accept an initial pitch pattern that will subsequently be reduced. In one embodiment, sacrificial substrate layer 140 is an oxide material (e.g., SiO₂) deposited to a thickness on the order of 5-50 nm. Overlying sacrificial substrate layer 140 is third hard mask layer 150. In one embodiment, third hard mask layer 150 is silicon nitride or other material that may serve, in one aspect, to protect sacrificial substrate layer 140 from undesired etching. Overlying third hard mask layer 150 is fourth hard mask layer 160. In one embodiment, fourth hard mask layer 160 is a material that has an etch rate different than an etch rate of third hard mask layer 150 for a particular etchant. In one embodiment, where third hard mask layer 150 is a silicon nitride material, fourth hard mask layer 160 is a carbon hard mask (CHM) deposited to a representative thickness on the order of 100 nm. Overlying fourth hard mask layer 160 is anti-reflective coating layer 170 deposited to a thickness on the order of 30 nm.

FIG. 1 shows the structure after the patterning of photoresist layer 180 on a surface of structure 100 (on a surface of anti-reflective coating layer 170). As illustrated, photoresist layer 180 (e.g., a negative photoresist material) is patterned to include openings through the photoresist to anti-reflective coating layer 170. In one embodiment, openings are formed of a width, W, on the order of 60 nanometers (nm) and a length (into the page) selected, in one embodiment, for a desired interconnect length. Openings 175 are patterned with a pitch, P₁, in one embodiment, on the order of 160 nm (from right edge to right edge as viewed).

FIG. 2 shows the structure of FIG. 1 following the patterning of third hard mask layer 150 through the mask defined by photoresist layer 180. FIG. 2 shows the structure of FIG. 1 following the removal of photoresist layer 180, anti-reflective coating layer 170 and fourth hard mask layer 160. The etch proceeds through third hard mask layer 150 to define openings 155 having a width, W, similar to the width of the openings through photoresist layer 180 (a 60 nm width) and a pitch, P₁ (e.g., on the order of 160 nm).

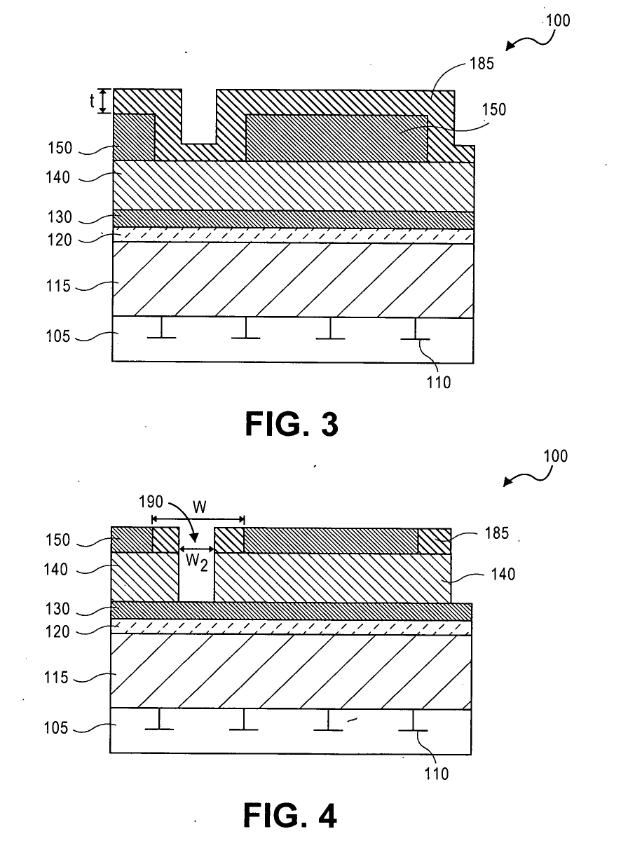

FIG. 3 shows the structure of FIG. 2 following the conformal deposition of spacer layer 185 on a surface of the structure. In one embodiment, spacer layer 185 is, for example, a material similar to sacrificial substrate layer 140 (e.g., an oxide). In one embodiment, spacer layer 185 is deposited by way of, for example, a chemical vapor deposition (CVD) process. The deposition is conformal in the sense that the deposited layer conforms to the surface of the substrate including on third hard mask layer 150 and onto a surface of sacrificial substrate layer 140. A representative thickness, t, of spacer layer 185 is on the order of 20 nm.

FIG. 4 shows the structure of FIG. 3 following the etching of spacer layer 185. In one embodiment, spacer layer 185 is etched by an anisotropic etchant, which, as viewed, etches vertically. A suitable anisotropic etchant where spacer layer 185 and sacrificial substrate layer are each an oxide is carbon tetrafluoride (CF₄). FIG. 4 shows that following an anisotropic etch, spacer layer 185 is removed from a surface of third hard mask layer 150 and a base of opening 155. FIG. 4 also shows a structure following a further anisotropic etch of structure 100 to reduce a thickness of third hard mask layer 150 and remaining vertical portions of spacer layer 185 while forming opening 190 through sacrificial substrate layer 140. The opening through sacrificial substrate layer 140 has a width W₂. Width W₂, is less than width, W originally established by the pattern of photoresist layer 180. Where width W was 60 nm, and spacer layer 185 has a thickness of 20 nm, width, W₂ is 20 nm (60 nm-20 nm-20 nm).

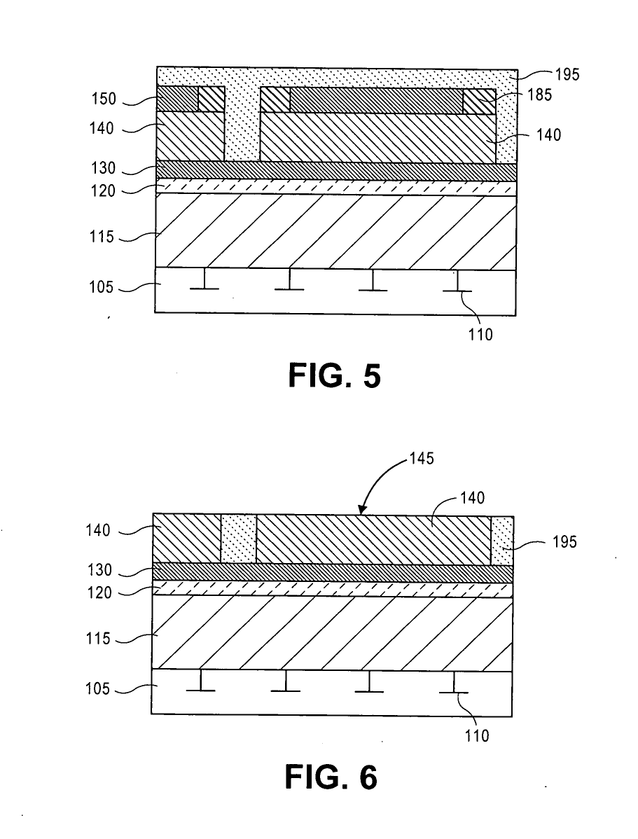

FIG. 5 shows the structure of FIG. 4 following the deposition of a target material over the surface and in opening 190. In one embodiment, target material 195 is a metal or other material that can be selectively modified relative to a material of sacrificial substrate layer 140 to favor the alignment of one polymer of a DSA block copolymer to the target material over the other. Representative metals include but are not limited to, tungsten, copper, titanium, titanium nitride, cobalt, ruthenium and aluminum. In one embodiment, tungsten is selected. Representative other materials include dielectric materials (e.g., Si₃N₄, SiO₂, SiCN, low k dielectric materials). Where sacrificial substrate layer 140 is a dielectric material, target material 195 of a dielectric will be a different dielectric material that can be selectively modified relative to sacrificial substrate layer 140.

FIG. 6 shows the structure of FIG. 5 following the planarization of the substrate surface. FIG. 6 shows the removal of target material from a surface of the structure leaving such target material 195 in openings 190 and also the removal of third hard mask layer 195 and spacer layer 185. One technique for planarizing substrate is a chemical mechanical polish. FIG. 6 shows superior surface 145 of the structure defined by sacrificial substrate layer 140 and periodically spaced lines of target material 195. At this point, an exposed surface of target material 195 may optimally be cleaned. For example, where target material 195 is a metal subject to oxidation, the surface may be cleaned by etch or wash to remove any oxidized material.

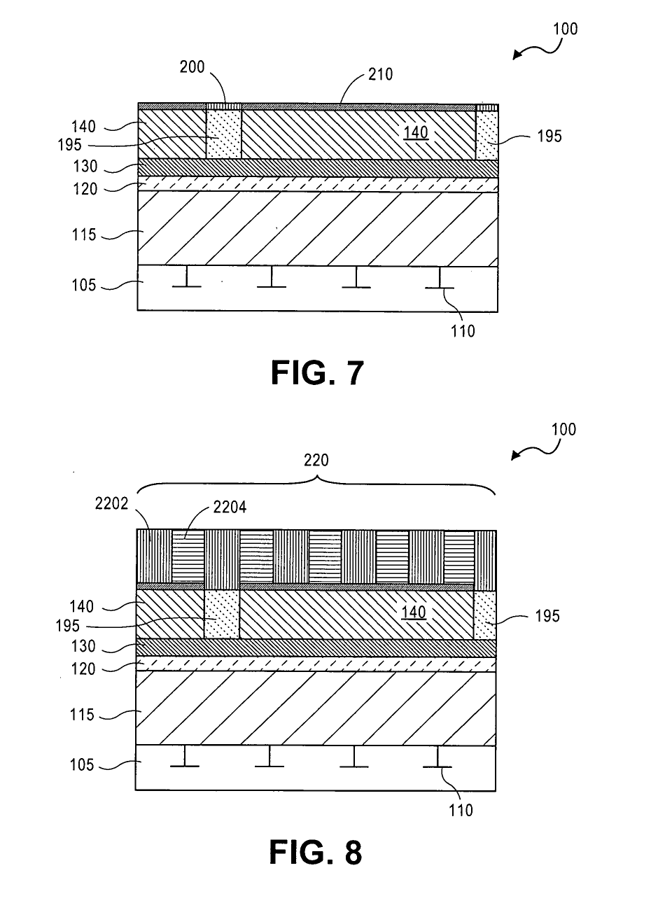

FIG. 7 shows the structure of FIG. 6 following the introduction of a directed self-assembly promotion (DSAAP) layer such as a pretreatment brush on a surface of target material 195 and not on a surface of sacrificial substrate layer 140. In one embodiment, DSAAP layer 200 is tailored for one of a block (polymer) of a block copolymer of a DSA material to be subsequently introduced on the structure so that the one block will have an affinity for attachment (alignment) to DSAAP layer 200. Such a DSAAP layer material is introduced to, in one embodiment, control an interaction of a subsequently introduced polymer of a block copolymer on the substrate.

DSAAP layer 200 serves to orient and register the lamellar bodies of the block composition. Representatively, DSAAP layer 200 is a polymer based on a similar monomer of one block of a block copolymer to be subsequently introduced. Representatively, where a block copolymer is polystyrene (PS)/polymethyl methacrylate (PMMA), DSAAP layer 200 is a polymer based on either PS or PMMA. In one embodiment, DSAAP layer 200 includes a reactive group such as hydroxyl groups that react with target material 195. Representatively, DSAAP layer 200 may be introduced to a thickness on the order of 5 nm to 10 nm. One technique is to apply the polymer as a liquid, bake and remove (rinse) any excess (any unreacted polymer).

FIG. 7 also shows the structure after the optional introduction of DSAAP layer 210 such as a neutral brush. Generally speaking, alignment control of a DSA process to achieve a vertical orientation of each block of a block copolymer is desired. One way to achieve vertical orientation is to control the interaction between the block copolymer-substrate interface and the block copolymer-air interface. The block copolymer-air interface is a function of the surface energies of the blocks of the copolymer. For a block copolymer of PS and PMMA, the polymers have similar surface energies which creates a generally neutral polymer-air interface. A substrate surface such as a surface of sacrificial substrate layer 140 may have a higher surface energy than the polymers of the block copolymer. In one embodiment, DSAAP layer 210 of a neutral brush may be introduced to reduce the surface energy of the substrate and generally equate such surface energy with that of the blocks of the block copolymer. In one embodiment, DSAAP layer 210 includes reactive groups such as hydroxyl groups to react with a surface of sacrificial substrate layer 140. DSAAP layer 210 may be deposited to a thickness on the order of 5 nm-10 nm as a liquid, baked and any excess removed by rinsing.

FIG. 8 shows the structure of FIG. 7 following the introduction of a block copolymer and the DSA process. FIG. 8 shows block copolymer 220 of, for example, a PS/PMMA introduced by spin-on process on a surface of the structure (a top surface as viewed). FIG. 8 shows that DSA block copolymer 220 aligns based on DSAAP layer 200. Representatively, where DSAAP layer 200 favored the PS block of the block copolymer relative to the PMMA block, the PS block will align with DSAAP layer 200 (attach to DSAAP layer 200). The alignment serves to orient the blocks as repeating lamellar bodies alternating one after the other in a repeating pattern across the surface of the substrate. FIG. 8 shows lamellar body 2202 of, for example, PS and lamellar body 2204 of PMMA. Each lamellar body is vertically oriented relative to a surface of sacrificial substrate layer 140 of the structure. In one embodiment, a molecular weight of the blocks (polymers) of a composition of DSA block copolymer 220 is tuned so that each lamellar body has a width, W₂, equal to a width of the target material.

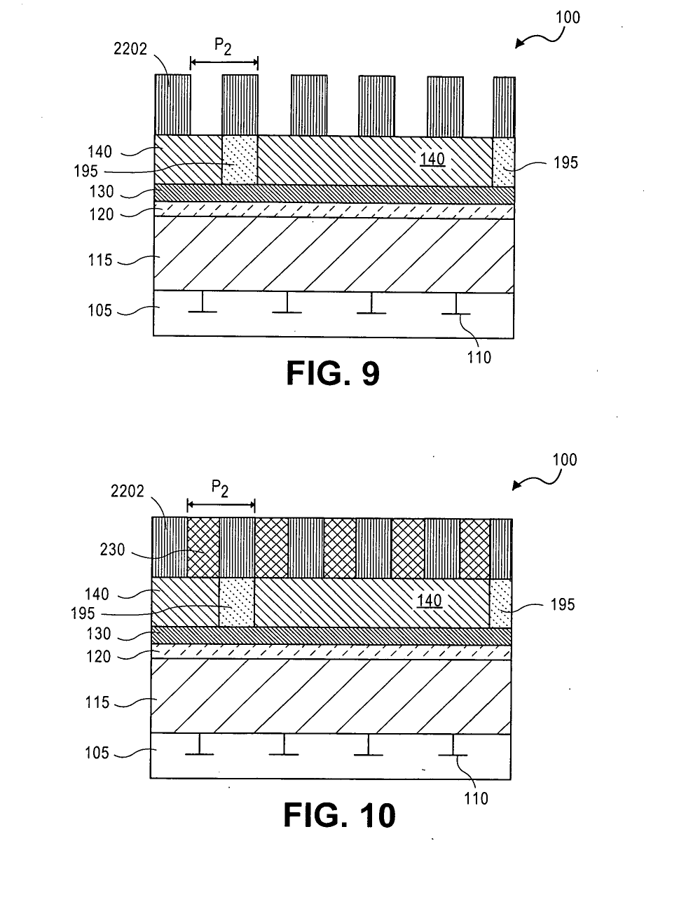

FIG. 9 shows the structure of FIG. 8 following the removal of the PMMA lamellar bodies (PMMA blocks) and the hardening of PS lamellar bodies (PS blocks 2202). In one embodiment, the lamellar bodies are hardened by a curing (e.g., a thermal cure). PMMA lamellar bodies may be removed by dry etch. FIG. 9 shows that following the removal of the PMMA lamellar bodies, a pitch between similar edges of PS lamellar bodies (e.g., a right edge as shown) is P₂. The pitch, P₂, is one-fourth the pitch, P₁.

FIG. 10 shows the structure of FIG. 9 following the introduction of a hard mask material complementary to the polymer pattern. FIG. 10 shows hard mask 230 of, for example, silicon nitride deposited in a complementary fashion in the sense that hard mask layer 230 complements or completes in a sense a layer on a surface of the structure with PS lamellar bodies 2202.

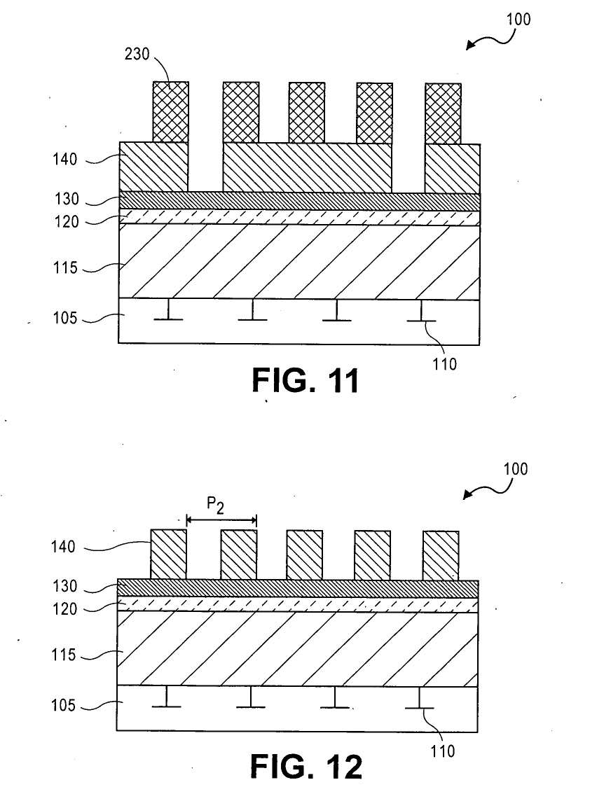

FIG. 11 shows the structure of FIG. 10 following the selective removal of PS lamellar bodies 2202 to leave patterned hard mask 230 on the surface of the structure. In one embodiment, PS lamellar bodies 2202 may be removed by an ashing process. FIG. 11 also shows the structure following the removal of target material 195. For a target material such as tungsten, such material may be removed by a chemical etch.

FIG. 12 shows the structure of FIG. 11 following the etching of sacrificial substrate layer 140 with hard mask 230 as a pattern. In one embodiment, the etch is an anisotropic etch (e.g., CF₄ for a sacrificial substrate layer of SiO₂) and selectively stops on second hard mask layer 130. FIG. 12 shows the structure following the removal of hard mask layers 230 and illustrates that sacrificial substrate layer 230 is patterned into structures having a pitch P₂ (measured right edge to right edge as viewed).

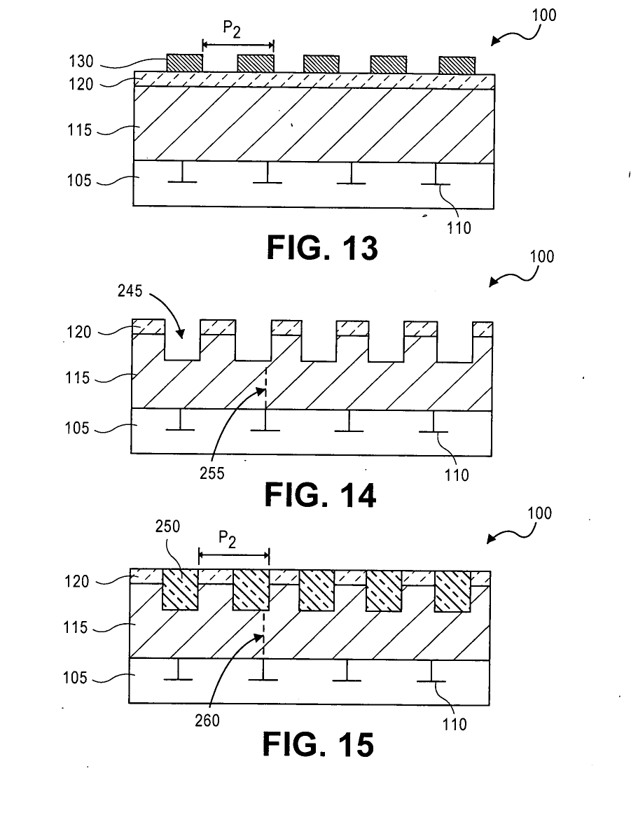

FIG. 13 shows the structure of FIG. 12 following the etching of second hard mask layer 130 using the patterned second substrate layer 140 as a mask. In this manner, the pattern of sacrificial substrate layer 140 is transferred to second hard mask layer 130. A suitable etchant to remove a second hard mask layer of TiN selective to a material for first hard mask layer 120 of silicon nitride is chlorine/argon Cl₂/Ar.

FIG. 14 shows the structure of FIG. 13 following a trench etch of ILD layer 115. In this embodiment, patterned second hard mask 130 is used as a mask and an etch proceeds through first hard mask layer 120 and into a desired depth of ILD layer 115 to form trenches 250 in the ILD layer. Where desired, vias 260 may subsequently be formed through ILD layer 115 to devices 110 by, for example, patterns of a mask (e.g., a photoresist) over areas of a surface of the substrate, the etching to devices 110 and then remove the mask. FIG. 14 shows the structure after trench (and via) formation after the removal of second hard mask layer 130.

FIG. 15 shows the structure of FIG. 14 following the introduction of interconnects 250 in trenches 250. In one embodiment, interconnects 250 are an electrically conductive copper material introduced by an electroplating process. Representatively, trenches 245 are seeded with a conductive seed material followed by plating of the interconnect material. Conductive vias 260 may be formed at a similar time. Alternatively, in the embodiment where devices 110 are circuit devices on a substrate, vias 260 may be formed prior to the formation of trenches 250. In such case, conductive vias 260 may be a tungsten material introduced by a deposition process.

The above method of pitch quartering uses DSA with a target material patterned as lines of loose pitch (larger pitch) as a guide or template in one technique for creating tight-pitched interconnect features. The method of using a target material as a guide for a chemically-selective DSAAP layer (e.g., a pretreatment brush) than spinning on a DSA material that selectively aligns to the target material over other material forming a surface of a structure can be used to produce pitches of other divisions of an original pitch, such as ½, ⅓, ⅕, ⅙, etc., an original loose pitch. The target material can be either sacrificial (as in the above method) or a permanent feature. The DSA polymers can be ones of various combinations of block copolymers. If spun-on during different alignment operations, multiple pitches can be patterned with multiple DSA materials.

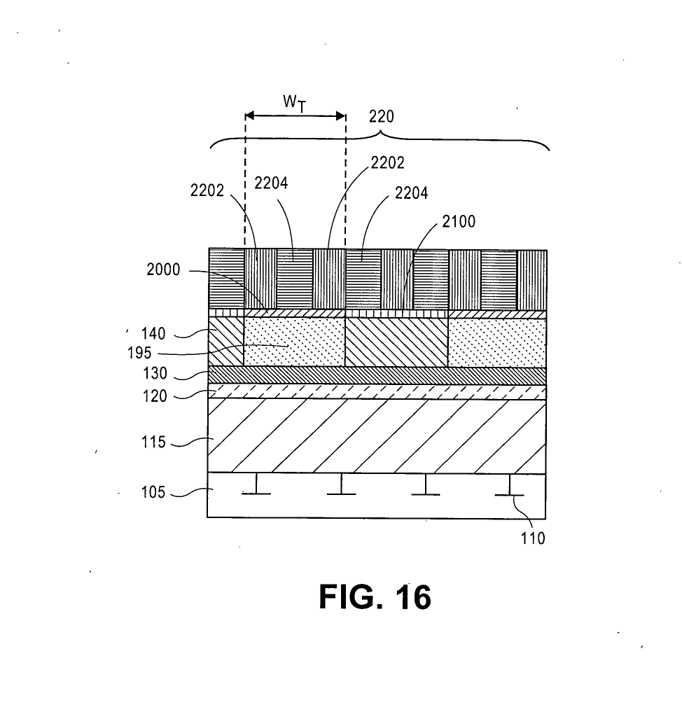

In the above embodiment, a target material (target material 190) was used to target or pin a single body of one block of a DSA block copolymer. In another embodiment, a target material can be used to target or pin more than one body of one block of a DSA block copolymer. FIG. 16 shows an embodiment of the structure analogous to FIG. 8 above where like reference numerals refer to like materials. In this embodiment, a width, W_{T} of target material 195 is greater than a width of a block of a DSA copolymer that is targeted so that multiple ones of the particular block are formed on the target material. In this embodiment, disposed on a surface of target material 195 of, for example, a metal is DSAAP layer 2000 that, in one embodiment, favors or prefers the alignment of one block of the block copolymer over the other. In one embodiment, DSAAP layer 2000 is similar to DSAAP layer 200 described above in that one block of a DSA block copolymer prefers it over the other. In another embodiment, DSAAP layer 2000 is a material that one block of a DSA block copolymer slightly prefers over the other. FIG. 16 also shows DSAAP layer 2100 disposed on a surface of dielectric layer 140. DSAAP layer 2100 may be similar to DSAAP layer 210 (see FIG. 8) and be neutral for either of two blocks of a DSA block copolymer. In another embodiment, DSAAP layer 2100 may be selected of a material that one block of a DSA block copolymer slightly prefers the material over the other (the block that did not prefer DSAAP layer 2000 prefers DSAAP layer 2100). FIG. 16 shows the structure after introduction of DSA block copolymer such as PS/PMMA and shows the assembly of the polymer into lamellar bodies across a surface of the substrate. In this embodiment, one block of a DSA block copolymer (e.g., PS) favors DSAAP layer 2000, and two bodies 2202 of the one block (e.g., PS) are disposed on target material 195. Two bodies 2202 of the one block (e.g., PS) are separated by body 2204 of the other block of the DSA block copolymer (e.g., PMMA). The lamellar bodies form a pattern of alternating bodies, one body after the other, across the surface of the structure similar to that described above with respect to FIG. 8. The width of a block is dependent on a molecular weight of a polymer in the block copolymer.

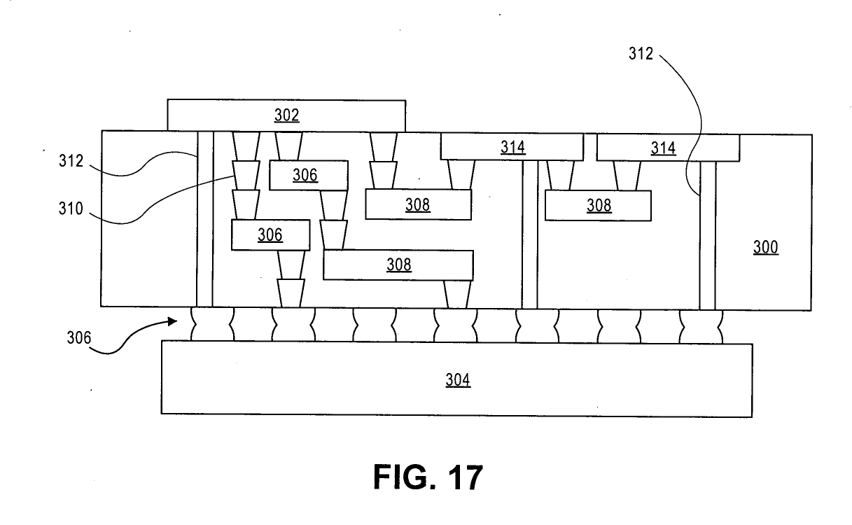

FIG. 17 illustrates interposer 300 that includes one or more embodiments. Interposer 300 is an intervening substrate used to bridge a first substrate 302 to second substrate 304. First substrate 302 may be, for instance, an integrated circuit die including interconnects formed using the DSA technique described above. Second substrate 304 may be, for instance, a memory module, a computer motherboard, or another integrated circuit die. Generally, the purpose of interposer 300 is to spread a connection to a wider pitch or to reroute a connection to a different connection. For example, interposer 300 may couple an integrated circuit die to ball grid array (BGA) 306 that can subsequently be coupled to second substrate 304. In some embodiments, first and second substrates 302/304 are attached to opposing sides of interposer 300. In other embodiments, first and second substrates 302/304 are attached to the same side of interposer 300. In further embodiments, three or more substrates are interconnected by way of interposer 300.

Interposer 300 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 308 and vias 310, including but not limited to through-silicon vias (TSVs) 312. Interposer 300 may further include embedded devices 314, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on interposer 300.

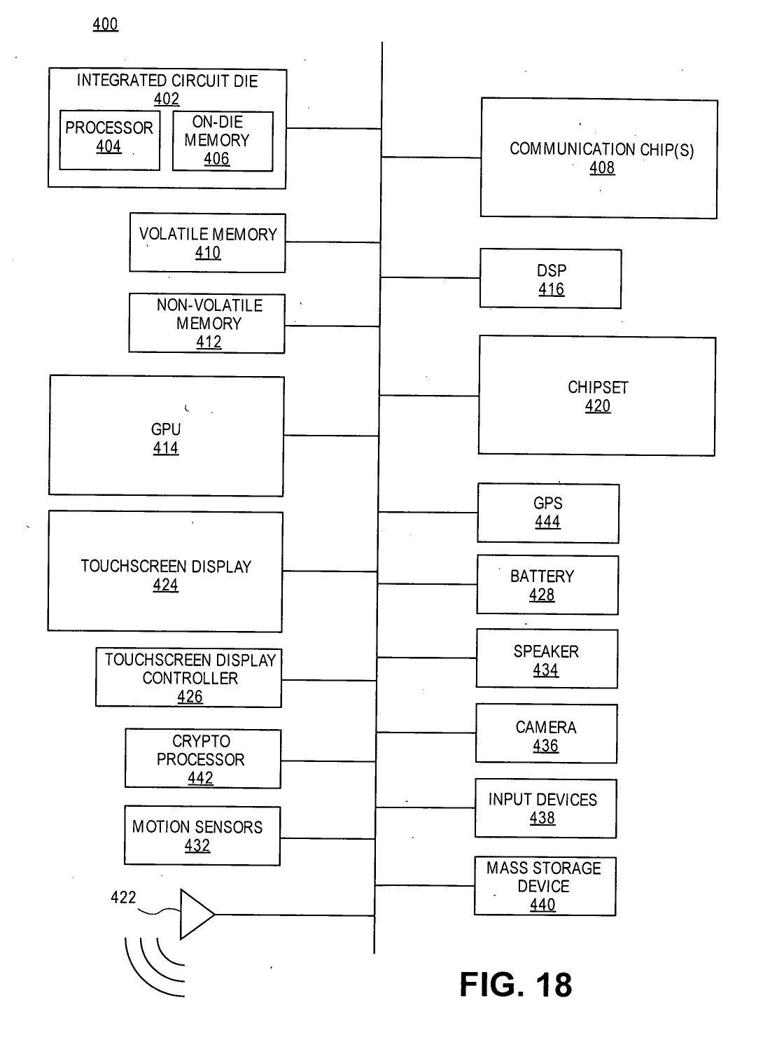

FIG. 18 illustrates computing device 400 in accordance with one embodiment. Computing device 400 may include a number of components. In one embodiment, these components are attached to one or more motherboards. In an alternate embodiment, these components are fabricated onto a single system-on-a-chip (SoC) die rather than a motherboard. The components in computing device 400 include, but are not limited to, integrated circuit die 402 and at least one communication chip 408. In some implementations communication chip 408 is fabricated as part of integrated circuit die 402. Integrated circuit die 402 may include CPU 404 as well as on-die memory 406, often used as cache memory, that can be provided by technologies such as embedded DRAM (eDRAM) or spin-transfer torque memory (STTM or STTM-RAM).

Computing device 400 may include other components that may or may not be physically and electrically coupled to the motherboard or fabricated within an SoC die. These other components include, but are not limited to, volatile memory 410 (e.g., DRAM), non-volatile memory 412 (e.g., ROM or flash memory), graphics processing unit 414 (GPU), digital signal processor 416, crypto processor 442 (a specialized processor that executes cryptographic algorithms within hardware), chipset 420, antenna 422, display or a touchscreen display 424, touchscreen controller 426, battery 428 or other power source, a power amplifier (not shown), global positioning system (GPS) device 444, compass 430, motion coprocessor or sensors 432 (that may include an accelerometer, a gyroscope, and a compass), speaker 434, camera 436, user input devices 438 (such as a keyboard, mouse, stylus, and touchpad), and mass storage device 440 (such as hard disk drive, compact disk (CD), digital versatile disk (DVD), and so forth).

Communications chip 408 enables wireless communications for the transfer of data to and from computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 408 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 400 may include a plurality of communication chips 408. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

Processor 404 of computing device 400 includes one or more devices, such as transistors or metal interconnects. Metal interconnects are formed in accordance with embodiments described above using DSA for pitch division. The term “processor” may refer to any device or portion of a device that processes electronic data from registers and/or memory to transform that electronic data into other electronic data that may be stored in registers and/or memory.

Communication chip 408 may also include one or more devices, such as transistors or metal interconnects. Metal interconnects are that are formed in accordance with embodiments.

In further embodiments, another component housed within computing device 400 may contain one or more devices, such as transistors or metal interconnects. Metal interconnects are formed in accordance with implementations.

In various embodiments, computing device 400 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 1200 may be any other electronic device that processes data.

### EXAMPLES

Example 1 is a method including forming a target pattern of a target material on a surface of a substrate; depositing a block copolymer on the surface of the substrate, wherein one of two blocks of the block copolymer preferentially aligns to the target material and the two blocks self assemble after deposition into repeating lamellar bodies on the surface of the substrate; selectively retaining one of the two blocks of the block copolymer over the other as a polymer pattern; and patterning the substrate with the polymer pattern.

In Example 2, the target material of the method of Example 1 includes a metal.

In Example 3, the metal of the method of Example 2 is selected from the group consisting of tungsten, copper, titanium, titanium nitride, cobalt, ruthenium and aluminum.

In Example 4, prior to depositing the block copolymer on the surface of the substrate, the method of any of Examples 1-3 includes depositing a directed self-assembly alignment promotion (DSAAP) layer tailored for one of the blocks of the block copolymer on the target material.

In Example 5, the DSAAP layer of the method of Example 4 is a first DSAAP layer and prior to depositing the block copolymer on the surface of the substrate, the method further includes depositing a second DSAAP layer that does not have a greater affinity for one of the blocks of the block copolymer on the surface of the substrate in an area free of the first DSAAP layer.

In Example 6, patterning the substrate with the polymer pattern of the method of any of Examples 1-4 includes depositing a sacrificial material complementary to the polymer pattern; removing the polymer pattern while leaving the sacrificial material as a complementary pattern on the substrate; and etching the substrate with the complementary pattern as a mask.

In Example 7, the substrate of the method of Example 6 includes a feature layer and at least one sacrificial substrate layer and etching the substrate with the complementary pattern as a mask includes etching the at least one sacrificial substrate layer.

In Example 8, the target pattern of the method of any of Examples 1-7 includes a pitch that is greater than a pitch of the polymer pattern.

In Example 9, selectively retaining one of the two blocks of the block copolymer of the method of any of Examples 1-8 includes selectively retaining the one with the affinity for the target material.

Example 10 is a method including forming a target pattern of a target material on a surface of a substrate, the target pattern including a first pitch; depositing a directed self-assembly alignment promotion (DSAAP) layer tailored for one of two blocks of a block copolymer on the target material; depositing a block copolymer on the surface of the substrate, wherein one of two blocks of the block copolymer aligns to the target material and the two blocks self assemble after deposition into repeating lamellar bodies on the surface of the substrate with an orientation perpendicular to the substrate; selectively removing the one of the two blocks of the block copolymer without the affinity for the target material to leave the other as a polymer pattern with a second pitch that is less than the first pitch; and patterning the substrate with the polymer pattern.

In Example 11, the target material of the method of Example 10 includes a metal.

In Example 12, the metal of the method of Example 11 is selected from the group consisting of tungsten, copper, titanium, titanium nitride, cobalt, rutherium and aluminum.

In Example 13, the DSAAP layer of the method of Example 10 is a first DSAAP layer and prior to depositing the block copolymer on the surface of the substrate, the method includes depositing a second DSAAP layer on the surface of the substrate in areas other than on the target material, wherein the DSAAP layer does not have a greater affinity for one of the blocks of the block copolymer on the target material.

In Example 14, patterning the substrate with the polymer pattern of the method of Example 10 includes depositing a sacrificial material complementary to the polymer pattern; removing the polymer pattern while leaving the sacrificial material as a complementary pattern on the substrate; and etching the substrate with the complementary pattern as a mask.

In Example 15, the substrate of the method of Example 14 includes a feature layer and at least one sacrificial substrate layer and etching the substrate with the complementary pattern as a mask includes etching the at least one sacrificial substrate layer.

Example 16 is a method including forming a target pattern of a target material on a surface of a substrate, the target pattern including a first pitch; depositing a block copolymer on the surface of the substrate, wherein one of two blocks of the block copolymer aligns to the target material and the two blocks self assemble after deposition into repeating lamellar bodies with an orientation perpendicular to the substrate; selectively removing the one of the two blocks of the block copolymer to leave the other as a polymer pattern; depositing a sacrificial material complementary to the polymer pattern; removing the polymer pattern while leaving the sacrificial material as a complementary pattern on the substrate; etching openings in the substrate with the complementary pattern as a mask, the polymer pattern including a second pitch that is less than the first pitch; and forming interconnects in the openings.

In Example 17, the substrate of the method of Example 16 includes a dielectric layer and etching openings in the substrate includes etching openings in the dielectric layer.

In Example 18, the target material of the method of Example 16 includes a metal.

In Example 19, the metal of the method of Example 18 is selected from the group consisting of tungsten, copper, titanium, titanium nitride, cobalt, ruthenium and aluminum.

In Example 20, prior to depositing the block copolymer on the surface of the substrate, the method of Example 16 includes depositing a directed self-assembly alignment promotion (DSAAP) layer tailored for one of the blocks of the block copolymer on the target material.

In Example 21, the DSAAP layer of the method of Example 20 is a first DSAAP layer and prior to depositing the block copolymer on the surface of the substrate, the method further includes depositing a second DSAAP layer that does not have a greater affinity for one of the blocks of the block copolymer on the surface of the substrate in areas other than on the surface of target material.

Example 22 is an apparatus including an integrated circuit substrate including a plurality of contact points and a dielectric layer on the contact points; a target pattern formed in a surface of the dielectric layer; and a self-assembled layer of repeating alternating bodies of a block copolymer, wherein one of two blocks of the block copolymer is preferentially aligned to the target pattern.

In Example 23, the apparatus of Example 22 further includes a directed self assembly alignment promotion (DSAAP) layer tailored for one of the blocks of the block copolymer on the target pattern between the target pattern and the self assembled layer.

In Example 24, the DSAAP layer of the apparatus of Example 23 is a first DSAAP layer and the apparatus further includes a second DSAAP layer that does not have a greater affinity for one of the blocks of the block copolymer on the surface of the substrate free of the target pattern.

In Example 25, the target pattern of the apparatus of Example 22 includes a metal.

In Example 26, the metal of the apparatus of Example 25 is selected from the group consisting of tungsten, copper, titanium, titanium nitride, cobalt, ruthenium and aluminum.

In Example 27, the target pattern of the apparatus of any of Examples 22-26 includes a plurality of lines disposed at a first pitch that is greater than a pitch of one of the alternating bodies of the block copolymer.

The above description of illustrated implementations, including what is described in the Abstract, is not intended to be exhaustive or to limit the invention to the precise forms disclosed. While specific implementations of, and examples for, the invention are described herein for illustrative purposes, various equivalent modifications are possible within the scope, as those skilled in the relevant art will recognize.

These modifications may be made in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
forming a target pattern of a target material on a surface of a substrate;
depositing a block copolymer on the surface of the substrate, wherein one of two blocks of the block copolymer preferentially aligns to the target material and the two blocks self assemble after deposition into repeating lamellar bodies on the surface of the substrate;
selectively retaining one of the two blocks of the block copolymer over the other as a polymer pattern; and
patterning the substrate with the polymer pattern.

2. The method of claim 1, wherein the target material comprises a metal.

3. The method of claim 2, wherein the metal is selected from the group consisting of tungsten, copper, titanium, titanium nitride, cobalt, ruthenium and aluminum.

4. The method of claim 1, wherein prior to depositing the block copolymer on the surface of the substrate, the method comprises depositing a directed self-assembly alignment promotion (DSAAP) layer tailored for one of the blocks of the block copolymer on the target material.

5. The method of claim 4, wherein the DSAAP layer is a first DSAAP layer and prior to depositing the block copolymer on the surface of the substrate, the method further comprises depositing a second DSAAP layer that does not have a greater affinity for one of the blocks of the block copolymer on the surface of the substrate in an area free of the first DSAAP layer.

6. The method of claim 1, wherein patterning the substrate with the polymer pattern comprises:
depositing a sacrificial material complementary to the polymer pattern;
removing the polymer pattern while leaving the sacrificial material as a complementary pattern on the substrate; and
etching the substrate with the complementary pattern as a mask.

7. The method of claim 6, wherein the substrate comprises a feature layer and at least one sacrificial substrate layer and etching the substrate with the complementary pattern as a mask comprises etching the at least one sacrificial substrate layer.

8. The method of claim 1, wherein the target pattern comprises a pitch that is greater than a pitch of the polymer pattern.

9. The method of claim 1, wherein selectively retaining one of the two blocks of the block copolymer comprises selectively retaining the one with the affinity for the target material.

10. A method comprising:
forming a target pattern of a target material on a surface of a substrate, the target pattern comprising a first pitch;
depositing a directed self-assembly alignment promotion (DSAAP) layer tailored for one of two blocks of a block copolymer on the target material;
depositing a block copolymer on the surface of the substrate, wherein one of two blocks of the block copolymer aligns to the target material and the two blocks self assemble after deposition into repeating lamellar bodies on the surface of the substrate with an orientation perpendicular to the substrate;
selectively removing the one of the two blocks of the block copolymer without the affinity for the target material to leave the other as a polymer pattern with a second pitch that is less than the first pitch; and
patterning the substrate with the polymer pattern.

11. The method of claim 10, wherein the target material comprises a metal.

12. The method of claim 11, wherein the metal is selected from the group consisting of tungsten, copper, titanium, titanium nitride, cobalt, rutherium and aluminum.

13. The method of claim 10, wherein the DSAAP layer is a first DSAAP layer and prior to depositing the block copolymer on the surface of the substrate, the method comprises depositing a second DSAAP layer on the surface of the substrate in areas other than on the target material, wherein the DSAAP layer does not have a greater affinity for one of the blocks of the block copolymer on the target material.

14. The method of claim 10, wherein patterning the substrate with the polymer pattern comprises:
depositing a sacrificial material complementary to the polymer pattern;
removing the polymer pattern while leaving the sacrificial material as a complementary pattern on the substrate; and
etching the substrate with the complementary pattern as a mask.

15. The method of claim 14, wherein the substrate comprises a feature layer and at least one sacrificial substrate layer and etching the substrate with the complementary pattern as a mask comprises etching the at least one sacrificial substrate layer.

16. A method comprising:
forming a target pattern of a target material on a surface of a substrate, the target pattern comprising a first pitch;
depositing a block copolymer on the surface of the substrate, wherein one of two blocks of the block copolymer aligns to the target material and the two blocks self assemble after deposition into repeating lamellar bodies with an orientation perpendicular to the substrate;
selectively removing the one of the two blocks of the block copolymer to leave the other as a polymer pattern;
depositing a sacrificial material complementary to the polymer pattern;
removing the polymer pattern while leaving the sacrificial material as a complementary pattern on the substrate;
etching openings in the substrate with the complementary pattern as a mask, the polymer pattern comprising a second pitch that is less than the first pitch; and
forming interconnects in the openings.

17. The method of claim 16, wherein the substrate comprises a dielectric layer and etching openings in the substrate comprises etching openings in the dielectric layer.

18. The method of claim 16, wherein the target material comprises a metal.

19. The method of claim 18, wherein the metal is selected from the group consisting of tungsten, copper, titanium, titanium nitride, cobalt, ruthenium and aluminum.

20. The method of claim 16, wherein prior to depositing the block copolymer on the surface of the substrate, the method comprises depositing a directed self-assembly alignment promotion (DSAAP) layer tailored for one of the blocks of the block copolymer on the target material.

21. The method of claim 20, wherein the DSAAP layer is a first DSAAP layer and prior to depositing the block copolymer on the surface of the substrate, the method further comprises depositing a second DSAAP layer that does not have a greater affinity for one of the blocks of the block copolymer on the surface of the substrate in areas other than on the surface of target material.

22. An apparatus comprising:
an integrated circuit substrate comprising a plurality of contact points and a dielectric layer on the contact points;
a target pattern formed in a surface of the dielectric layer; and
a self-assembled layer of repeating alternating bodies of a block copolymer, wherein one of two blocks of the block copolymer is preferentially aligned to the target pattern.

23. The apparatus of claim 22, further comprising a directed self assembly alignment promotion (DSAAP) layer tailored for one of the blocks of the block copolymer on the target pattern between the target pattern and the self assembled layer.

24. The apparatus of claim 23, wherein the DSAAP layer is a first DSAAP layer and the apparatus further comprises a second DSAAP layer that does not have a greater affinity for one of the blocks of the block copolymer on the surface of the substrate free of the target pattern.
